(19) United States
(12) Patent Application Publication
(10) Pub. No.: US 2025/0075323 A1
(43) Pub. Date: Mar. 6, 2025

(54) SUBSTRATE SUPPORT, THIN FILM PROCESSING DEVICE, AND THIN FILM DEPOSITION CONTROL METHOD USING THE SAME

(71) Applicant: SAMSUNG ELECTRONICS CO., LTD., Suwon-si (KR)

(72) Inventors: SungYoung YOON, Suwon-si (KR); Sung-Yeol KIM, Suwon-si (KR); Jaehyun CHOI, Suwon-si (KR); Meehyun LIM, Suwon-si (KR); Dongseok KANG, Suwon-si (KR); Youngil KANG, Suwon-si (KR); Dongsu KIM, Suwon-si (KR)

(73) Assignee: SAMSUNG ELECTRONICS CO., LTD., Suwon-si (KR)

(21) Appl. No.: 18/442,991

(22) Filed: Feb. 15, 2024

(30) Foreign Application Priority Data
Aug. 30, 2023 (KR) 10-2023-0114648

(51) Int. Cl. C23C 16/458; C23C 16/509; C23C 16/52

(52) U.S. Cl. CPC C23C 16/4586; C23C 16/509; C23C 16/52

(57) ABSTRACT

A substrate support according to an embodiment includes: a body portion that has a substrate disposition surface at an upper portion thereof; an RF electrode that is disposed inside the body portion; a heater electrode that is disposed below the RF electrode; and a shaft that is formed on a lower portion surface disposed at an opposite side of the substrate disposition surface and has a hollow. The RF electrode includes a first outer RF electrode surrounding the outside of the substrate disposition surface, an inner RF electrode disposed parallel to the substrate disposition surface below the substrate disposition surface, a second outer RF electrode disposed between the inner RF electrode and the heater electrode, an inner electrode conductor having one end connected to the inner RF electrode to be disposed to penetrate the shaft, and an outer electrode conductor having one end connected to the second outer RF electrode to be disposed to penetrate the shaft, and the first outer RF electrode, the inner RF electrode, and the second outer RF electrode are spaced apart from each other to have a non-contact structure.

### CROSS-REFERENCE TO RELATED APPLICATION

This application claims priority to Korean Patent Application No. 10-2023-0114648 filed at the Korean Intellectual Property Office on Aug. 30, 2023, the entire contents of which are incorporated herein by reference.

### BACKGROUND

### 1. Field

The present disclosure relates to a substrate support, a thin film processing device, and a thin film deposition control method using the same.

### 2. Description of Related Art

A semiconductor process is a process of reducing and forming an electric circuit on a wafer. In the semiconductor fabrication process, materials such as a semiconductor, a conductor, an insulator, and the like are deposited to manufacture an element. A wiring process for connecting elements is performed after a shape of the element is formed by removing unnecessary portions. Then a portion other than a wiring portion is removed and an insulator is deposited between wires.

A deposition process within the semiconductor fabrication process may include forming a conductive thin film or an insulating thin film on a substrate, and may also include forming a film that divides, connects, and protects circuits. The deposition process is generally divided into a physical vapor deposition (PVD) method and a chemical vapor deposition (CVD) method. However, as micronization process technology has recently improved, an atomic layer deposition (ALD) process is also being widely used.

The deposition process may be performed by applying a radio frequency (RF) power supply to a reactor while a vacuum is maintained to transfer heat to a substrate seated on a heater, and by then introducing a chemical gas in a plasma state to obtain desired film quality. There has recently been a demand for advancement in technologies such as the heater, the plasma, a precursor, or the like.

The heater is an important component for obtaining the desired film quality in the deposition process, and research and development on the heater are actively underway. In the case of a conventional heater made of a metal, there are problems related to thermal deformation and poor corrosion resistance at a high temperature (e.g., 400 degrees Celsius or higher). Currently, a heater manufactured using AlN that has excellent thermal conductivity and high plasma corrosion resistance is desirable.

Film quality such as film uniformity, film thickness, or the like in the deposition process is affected by uniformity and a temperature of a dielectric layer, so that temperature adjustment is important. Sinterability at a high temperature of 600 degrees Celsius or higher during the deposition process is low depending on an internal electrode and an electrode connection structure so that there is a known problem of cracking caused by heat. Thus, there is a need to develop technology addressing this problem.

### SUMMARY

The present disclosure provides a substrate support, a thin film processing device, and a thin film deposition control method using the same that independently control RF electric power and a temperature of a heater through a disposition structure of a plurality of RF electrodes and a heater electrode.

In addition, the present disclosure provides a substrate support, a thin film processing device, and a thin film deposition control method using the same that change a connection structure for connecting RF electrodes and an external circuit to solve a problem of cracking caused by heat that occurs due to weak sinterability at a bent portion of a conventional connection structure for connecting RF electrodes and an external circuit at a high temperature.

According to an aspect of the disclosure, a substrate support includes: a body portion including: substrate disposition surface on an upper portion thereof; and a lower portion surface on a surface of the body portion opposite from the substrate disposition surface; a radio frequency (RF) electrode disposed inside the body portion; a heater electrode disposed between the RF electrode and the lower portion surface; and a shaft that is formed on the lower portion surface, wherein the shaft includes a hollow inner portion, wherein the RF electrode includes: a first outer RF electrode disposed along a perimeter of the substrate disposition surface; an inner RF electrode disposed parallel to and beneath the substrate disposition surface; a second outer RF electrode disposed between the inner RF electrode and the heater electrode; an inner electrode conductor having one end connected to the inner RF electrode, wherein the inner electrode conductor is disposed within the shaft; and an outer electrode conductor having one end connected to the second outer RF electrode, wherein the outer electrode conductor is disposed within the shaft, and wherein the first outer RF electrode, the inner RF electrode, and the second outer RF electrode are spaced apart from each other to have a non-contact structure.

According to an aspect of the disclosure, a substrate support includes: a body portion including: a substrate disposition surface on an upper portion thereof; and a lower portion surface on a surface of the body portion opposite from the substrate disposition surface; a radio frequency (RF) electrode disposed inside the body portion; a heater electrode disposed between the RF electrode and the lower portion surface; and a shaft that is formed on the lower portion surface, wherein the shaft includes a hollow inner portion, wherein the RF electrode including: a first outer RF electrode, an inner RF electrode, a second outer RF electrode, an inner electrode conductor having one end connected to the inner RF electrode, wherein the inner electrode conductor is disposed within the shaft, and an outer electrode conductor having one end connected to the second outer RF electrode, wherein the outer electrode conductor is disposed within the shaft, wherein the inner electrode conductor and the outer electrode conductor each have a straight line shape, wherein the first outer RF electrode, the inner RF electrode, and the second outer RF electrode are spaced apart from each other in a stacked configuration, wherein within the stacked configuration the first outer RF electrode is closest to the substrate disposition surface, the inner RF electrode is next closest to the substrate disposition surface, and the second outer RF electrode is farthest from the substrate disposition surface, wherein the first outer RF electrode and the second outer RF electrode are configured to couple through non-contact capacitive coupling, and wherein the inner electrode conductor is connected to a first impedance controller and the outer electrode conductor is connected to a second impedance controller, and each of the first impedance controller and the second impedance controller are configured to independently control an impedance of the inner electrode conductor and the outer electrode conductor, respectively.

The embodiments may use a plurality of RF electrodes and a heater electrode, may improve thin film quality through control of each of the plurality of RF electrodes and the heater electrode, and may straighten a connection structure of the plurality of RF electrodes to solve a problem of cracking caused by heat that occurs due to a decrease in sinterability in a conventional art.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a view of a substrate support according to an embodiment;

FIG. 2 is a view of a substrate support according to an embodiment;

FIG. 3 is a view of a substrate support according to an embodiment;

FIG. 4 is a view of a substrate support according to an embodiment;

FIG. 5 is a view of a substrate support according to an embodiment;

FIG. 6 is a block diagram describing a substrate support according to an embodiment;

FIG. 7 is a view of an RF electrode of the substrate support according to an embodiment;

FIG. 8 is a view of an RF electrode of the substrate support according to an embodiment;

FIGS. 9A, 9B, and 9C are views shown to describe an effect of the substrate support according to an embodiment;

FIGS. 10A, 10B, and 10C are views shown to describe an effect of the substrate support according to an embodiment;

FIGS. 11A, 11B, and 11C are views shown to describe an effect of the substrate support according to an embodiment; and

FIG. 12 is a view of a thin film processing device according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

Throughout the specification, it will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Terms such as “unit”, “module”, “member”, and “block” may be embodied as hardware or software. According to embodiments, a plurality of “unit”, “module”, “member”, and “block” may be implemented as a single component or a single “unit”, “module”, “member”, and “block” may include a plurality of components.

Herein, the expression “at least one of a, b or c” indicates “only a,” “only b,” “only c,” “both a and b,” “both a and c,” “both b and c,” or “all of a, b, and c.”

Hereinafter, a substrate support 10, a thin film processing device 20, and a thin film deposition control method using the same according to an embodiment of the present disclosure will be described in more detail with reference to the drawings.

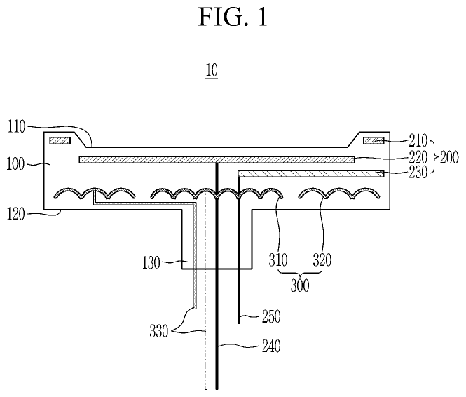

FIG. 1 is a view shown to describe the substrate support according to an embodiment.

FIG. 1 shows a cross-section of the substrate support 10. As shown in FIG. 1, the substrate support 10 according to the present disclosure includes a body portion 100 having a substrate disposition surface 110 on an upper portion thereof, a radio frequency (RF) electrode 200 disposed inside the body portion 100, a heater electrode 300 disposed below the RF electrode 200, and a shaft 130 formed on a lower portion surface 120 disposed at an opposite side of the substrate disposition surface 110 and having a hollow inner portion. The RF electrode 200 may be formed from multiple electrodes.

The RF electrode 200 may include a first outer RF electrode 210, an inner RF electrode 220, and a second outer RF electrode 230, and the RF electrode 200 may be configured to have a non-contact structure in which the first outer RF electrode 210, the inner RF electrode 220, and the second outer RF electrode 230 are spaced apart from each other.

Specifically, the RF electrode 200 may include the first outer RF electrode 210 that surrounds the outside of the substrate disposition surface 110 at an upper end of the substrate disposition surface 110, the inner RF electrode 220 disposed in parallel with the substrate disposition surface 110 below the substrate disposition surface 110, and the second outer RF electrode 230 disposed between the inner RF electrode 220 and the heater electrode 300. The second outer RF electrode 230 may couple with the first outer RF electrode 210 through non-contact capacitive coupling.

For the non-contact capacitive coupling, a radius of the second outer RF electrode 230 may be the same as a radius of the first outer RF electrode 210, and the coupling may be achieved between opposing areas of the respective electrodes.

The non-contact capacitive coupling may be a method of transferring alternating current electrical energy through capacitance between two conductors spaced apart and not in contact with one another, and may be an easy method for transferring power via a radio frequency (RF) signal.

As may be seen in the description below, the substrate support 10 according to the present disclosure may adjust impedance of the outer RF electrodes 210 and 230 that are coupled through the non-contact capacitive coupling. The substrate support 10 according to the present disclosure does not require a separate connection structure with weak sinterability, thus the configuration of the substrate support of the present disclosure ensures sinterability even in a process requiring a temperature of 650 degrees or higher.

In other words, the substrate support 10 according to the present disclosure may be used without temperature restriction, and is specifically configured such that sinterability is ensured even at a high temperature of 650 degrees or higher.

As shown in FIG. 1, each of electrode conductors 240 and 250 for connecting an external circuit may be connected to the outer RF electrodes 210 and 230 and the inner RF electrode 220. The shaft 130 having the hollow inner portion may have a minimum inner diameter so that electrode conductors connected to each of the RF electrode 200 and the heater electrode 300 pass through the shaft 130.

The electrode conductors 240 and 250 may include an inner electrode conductor (or a conductor for inner electrode) 240 having one end connected to the inner RF electrode 220 to be disposed to penetrate the shaft 130, and an outer electrode conductor (or a conductor for outer electrode) 250 having one end connected to the second outer RF electrode 230 to be disposed to penetrate the shaft 130.

Because the first outer RF electrode 210 performs non-contact capacitive coupling with the second outer RF electrode 230, the substrate support 10 according to the present disclosure does not require an electrode conductor directly connected to the first outer RF electrode 210.

In addition, the second outer RF electrode 230 may be a structure disposed below the inner RF electrode 220, and the outer electrode conductor 250 that has to penetrate the shaft 130 may be connected to the second outer RF electrode 230 to be disposed in a straight line. In other words, it is not necessary to avoid the inner RF electrode 220 to separately dispose the outer electrode conductor 250, and both the second outer RF electrode 230 and the inner RF electrode 220 may be stacked as shown in FIG. 1 so as to reach a region where a hollow inner portion of the shaft 130 is projected so that the inner electrode conductor 240 and the outer electrode conductor 250 are disposed in a straight line without contacting each other.

Generally, in multi-electrode applications, an outer RF electrode is disposed at the outside of an inner RF electrode to surround the inner RF electrode and a connection structure connected to each electrode is required. In this case, the connection structure is a structure in which one end thereof is connected to each RF electrode and the other end thereof extends through a shaft connected to a lower portion of a substrate support, and in the case of the connection structure (e.g., an electrode conductor, a jumper, or the like) that is connected to the outer RF electrode disposed at the outside of the inner RF electrode to exit through the shaft, a bent portion is normally included.

In other words, when the outer RF electrode is disposed outside a region where a hollow inner portion of the shaft is projected, the connection structure of the outer RF electrode has to be disposed so as not to contact the inner RF electrode, so that the connection structure connected to the outer RF electrode may not have a straight-line structure and inevitably includes one or more bent portions.

A chemical vapor deposition (CVD) method among thin film deposition processes is a process of depositing a thin film using a high temperature heater. In related applications, there is a known problem in which a temperature of the process increases during a process of reducing thermal stress between processes. It is necessary to prepare for a high temperature process of 650 degrees or higher in the process of reducing the thermal stress.

However, the bent portion of the connection structure in the conventional art has a problem of low sinterability compared with a portion of the connection structure made of a straight line. At a high temperature of about 550 degrees, the bent portion does not cause a problem, but at the high temperature of 650 degrees or higher, a problem of cracking caused by heat occurs in the bent portion due to the low sinterability.

The substrate support 10 according to the present disclosure improves thin film quality by including the multi-electrode and does not include a connection structure (that is, an electrode conductor) connected to the first outer RF electrode 210 that surrounds the inner RF electrode 220, so that the present disclosure is characterized in that the electrode conductor does not have a bent portion. Accordingly, the present disclosure has an effect of preventing the cracking caused by heat from occurring due to the low sinterability even at the high temperature of 650 degrees or higher.

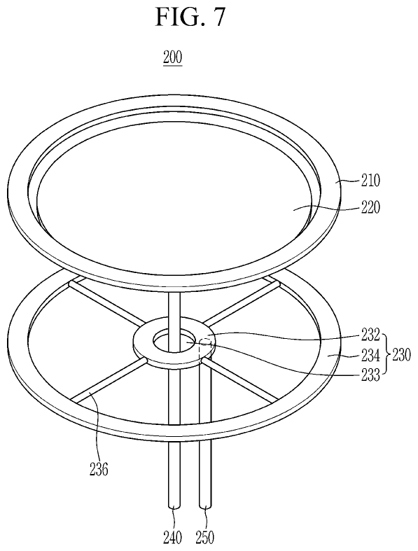

FIG. 1 shows a cross-section of the substrate support 10 according to the present disclosure, the first outer RF electrode 210 may have a ring shape surrounding the substrate disposition surface 110 at which a disk-shaped substrate is disposed (see FIG. 7 below), and the first outer RF electrode 210 of the ring shape may be disposed parallel to the substrate disposition surface 110.

The first outer RF electrode 210 may be disposed on a plane higher than a height at which the inner RF electrode 220 is disposed based on the lower portion surface 120 of the substrate support 10, and may be disposed on the same line as the substrate disposition surface 110.

The inner RF electrode 220 may be disposed below the substrate disposition surface 110, may be disposed parallel to the substrate disposition surface 110, and may have a disk shape, and the second outer RF electrode 230 may be disposed below the inner RF electrode 220.

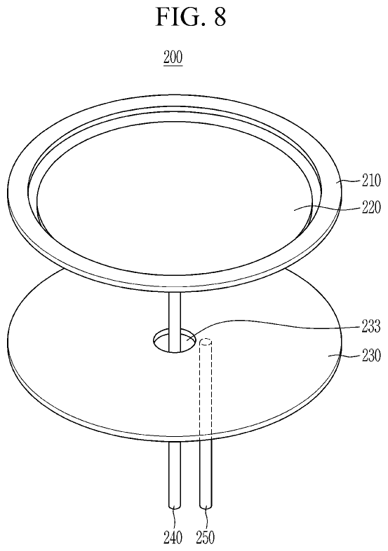

The second outer RF electrode 230 may have the same radius as a radius of the first outer RF electrode 210 to have a surface facing the first outer RF electrode 210 disposed above the second outer RF electrode 230. In addition, the inner electrode conductor 240 connected to the inner RF electrode 220 to head for the shaft 130 has to pass through a center of the second outer RF electrode 230, so that a predetermined hole is included in the center of the second outer RF electrode 230. A structure of the RF electrode 200 will be described in detail in FIGS. 7 and 8 below.

In addition, the substrate support 10 according to the present disclosure may include a plurality of heater electrodes 300 disposed on one plane for distribution control (or dispersion control), the plurality of heater electrodes 300 may include a central portion (that is, a first heater electrode 310 disposed within a perimeter of the substrate disposition surface 110) disposed within a center portion of the substrate disposition surface 110 and a second heater electrode 320 disposed outside the first heater electrode 310 (i.e., disposed between the first heater electrode 310 and an outer edge of the substrate disposition surface 110), and each of the plurality of heater electrodes 300 may be connected to a heater electrode conductor (or a conductor for heater electrode) 330 to be connected to an external circuit.

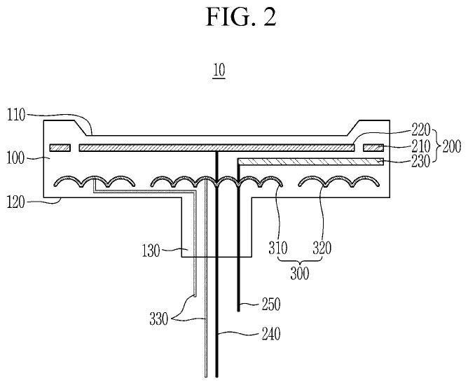

FIG. 2 is a view shown to describe a substrate support according to an embodiment.

Unlike the embodiment of FIG. 1 in which the first outer RF electrode 210 is disposed on a plane higher than a height of the inner RF electrode 220, as shown in FIG. 2, the first outer RF electrode 210 may be disposed on the same plane as the inner RF electrode 220 based on the lower portion surface 120 of the substrate support 10 in the substrate support 10 according to the present disclosure.

A distance between a substrate to be disposed on the substrate disposition surface 110 and the first outer RF electrode 210 of the embodiment of FIG. 2 may be farther than that of the embodiment shown in FIG. 1. As the distance between the substrate and the first outer RF electrode 210 is closer, a variable range of an electric field on a surface of the substrate may become wider, so that the embodiment of FIG. 2 may have a narrower variable range of the electric field than the embodiment of FIG. 1.

However, in the substrate support 10 according to the present disclosure, the second outer RF electrode 230 may perform non-contact capacitive coupling with the first outer RF electrode 210. As a distance between the second outer RF electrode 230 and the first outer RF electrode 210 of the embodiment of FIG. 2 becomes closer than that of the embodiment of FIG. 1, the non-contact capacitive coupling may become stronger, so that the variable range of the electric field varies depending on the distance between the second outer RF electrode 230 and the first outer RF electrode 210.

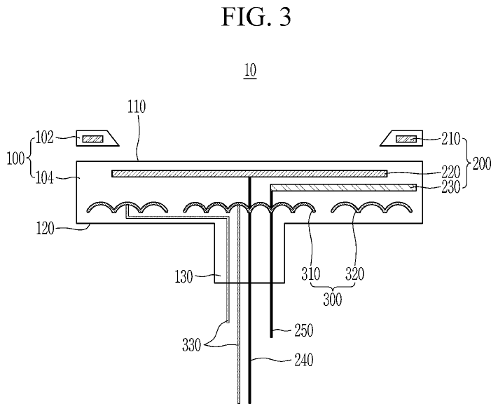

FIG. 3 is a view shown to describe a substrate support according to an embodiment.

As shown in FIG. 3, the body portion 100 may include a first body portion 102 at which the first outer RF electrode 210 is disposed, and a second body portion 104 at which the substrate disposition surface 110, the inner RF electrode 220, the second outer RF electrode 230, and the heater electrode 300 are disposed, and the first body portion 102 and the second body portion 104 may be disposed to be spaced apart from each other.

The first body portion 102 surrounds the first outer RF electrode 210 that has a ring shape, and the first outer RF electrode 210 is not directly exposed to plasma.

The first body portion 102 may have the same ring shape as a shape of the first outer RF electrode 210, and when the first body portion 102 is disposed to be spaced apart from the second body portion 104 as shown in FIG. 3, the first body portion 102 may be connected and fixed to a structure other than the second body portion 104.

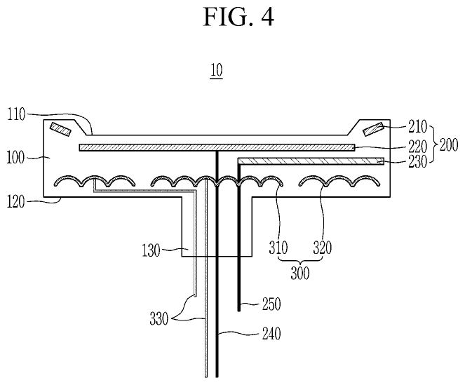

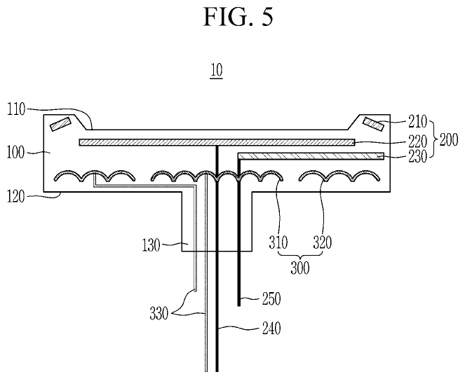

FIG. 4 and FIG. 5 are views shown to describe substrate supports according to other embodiments.

As shown in FIG. 4 and FIG. 5, the first outer RF electrode 210 may have a ring shape. The first outer RF electrode 210 may have a shape that is inclined as it moves from an inner circumference of the ring shape to an outer circumference of the ring shape so that the ring shape is disposed to have a constant angle between 0 and 90 degrees with respect to the substrate disposition surface 110.

The embodiment shown in FIG. 4 is a case where the first outer RF electrode 210 is disposed to face upward as it moves from an inner circumference thereof to an outer circumference thereof. The embodiment shown in FIG. 4 is an example in which a distance between the first outer RF electrode 210 and the second outer RF electrode 230 increases as the first outer RF electrode 210 moves from an inner circumference thereof to an outer circumference thereof. In other words, a height of an outer circumference of the first outer RF electrode 210 with respect to the lower portion surface 120 is higher than a height of an inner circumference of the first outer RF electrode 210 with respect to the lower portion surface 120.

Unlike the embodiment of FIG. 4, the embodiment shown in FIG. 5 is a case where the first outer RF electrode 210 is disposed to face downward as it moves from an inner circumference thereof to an outer circumference thereof. A height of an outer circumference of the first outer RF electrode 210 with respect to the lower portion surface 120 is lower than a height of an inner circumference of the first outer RF electrode 210 with respect to the lower portion surface 120.

As shown in FIG. 4 and FIG. 5, if the first outer RF electrode 210 has an inclined structure, an area of the first outer RF electrode 210 that forms non-contact capacitive coupling with the second outer RF electrode 230 may become different and an angle between the first outer RF electrode 210 and the second outer RF electrode 230 may become different, so that there may be a difference in a degree of the non-contact capacitive coupling.

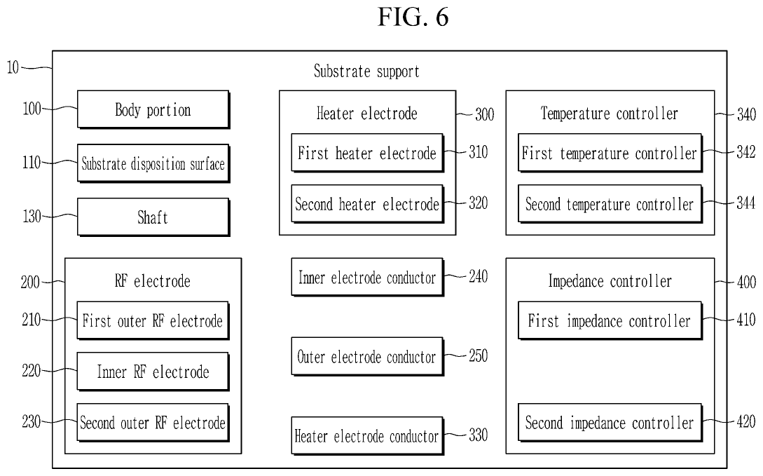

FIG. 6 is a view shown to describe the substrate support according to an embodiment.

FIG. 6 is a view for describing a configuration of the substrate support 10. The substrate support 10 may include an impedance controller (or an impedance control unit) 400 that is connected to the electrode conductors 240 and 250 connected to the RF electrode 200 to control impedance of the RF electrode 200.

Specifically, the electrode conductors 240 and 250 may include the inner electrode conductor 240 with one end connected to the inner RF electrode 220 and the outer electrode conductor 250 with one end connected to the second outer RF electrode 230, and the impedance controller 400 may include a first impedance controller 410 and a second impedance controller 420 that are connected to the other ends of the inner electrode conductor 240 and the outer electrode conductor 250 to independently control the impedance.

That is, the impedance controller 400 may include the first impedance controller 410 connected to the inner electrode conductor 240 connected to the inner RF electrode 220 to control impedance of the inner RF electrode 220, and the second impedance controller 420 connected to the outer electrode conductor 250 connected to the second outer RF electrode 230 to control impedance of the second outer RF electrode 230. Although the second impedance controller 420 is directly connected to the second outer RF electrode 230, the second impedance controller 420 may also control the first outer RF electrode 210 electrically connected to the second impedance controller 420.

The first and second impedance controllers 410 and 420 connected to the inner RF electrode 220 and the second outer RF electrode 230 may control inner and outer impedances to have an effect of independently controlling a thickness and a physical property of the thin film.

The impedance controller 400 may include an inductor and a vacuum variable capacitor (VVC) that may cause a resonance effect. Accordingly, each of the first impedance controller 410 and the second impedance controller 420 may include the vacuum variable capacitor (VVC).

In addition, the substrate support 10 may include a temperature controller (or a temperature control unit) 340 that controls temperatures of the plurality of heater electrodes 300. The temperature controller 340 may include a first temperature controller 342 and a second temperature controller 344 connected to heater electrode conductors 330 connected to the first heater electrode 310 and the second heater electrode 320.

The first heater electrode 310 and the second heater electrode 320 may be connected to the temperature controller 340 by the heater electrode conductor 330, and the temperature controller 340 may control a temperature of each of the first heater electrode 310 and the second heater electrode 320. One temperature controller 340 may independently adjust the temperature of each of the first heater electrode 310 and the second heater electrode 320, but the first temperature controller 342 and the second temperature controller 344 may be respectively connected to the first heater electrode 310 and the second heater electrode 320 so that the first temperature controller 342 and the second temperature controller 344 independently adjust the temperatures of the first heater electrode 310 and the second heater electrode 320.

In the drawings, the plurality of heater electrodes 300 are divided into two regions (that is, the first heater electrode 310 and the second heater electrode 320), but the number and positions of heater electrodes are not necessarily limited thereto, and the plurality of heater electrodes 300 may be divided at each position where independent temperature control is required. In this case, temperatures of the plurality of heater electrodes 300 may be independently controlled.

FIG. 7 is a view shown to describe the RF electrode of the substrate support according to an embodiment.

As shown in FIG. 7, the first outer RF electrode 210 may have a ring shape, and the inner RF electrode 220 disposed below the first outer RF electrode 210 may have a disk shape.

For example, a radius of the inner RF electrode 220 may be 150 mm or more and 152 mm or less, so that an effect may be concentrated on a central portion where the inner RF electrode 220 is disposed. In addition, an interior diameter of the first outer RF electrode 210 that has the ring shape and is disposed above the inner RF electrode 220 may be 153±1 mm, and an exterior diameter of the first outer RF electrode 210 may be 155±1 mm, so that an impedance adjustment effect may be concentrated on the outer region.

Additionally, a distance between a lower end of the first outer RF electrode 210 and an upper end of the second outer RF electrode 230 may be less than or equal to 2 mm to maximize a coupling effect between the first outer RF electrode 210 and the second outer RF electrode 230.

According to an embodiment, as shown in FIG. 7, the second outer RF electrode 230 disposed below the inner RF electrode 220 may have a wheel shape.

Specifically, the second outer RF electrode 230 may include an inner ring 232 including a hole 233 through which the inner electrode conductor 240 connected to the inner RF electrode 220 passes, and the inner ring 232 may be disposed at a center of the second outer RF electrode 230. The second outer RF electrode 230 may have a structure including an outer ring 234 spaced apart from the inner ring 232 to be formed on the same plane. In this case, one or more straight jumpers 236 connecting the inner ring 232 and the outer ring 234 may be included in the second outer RF electrode 230.

Assuming that there is no straight jumper 236, the inner ring 232 of the second outer RF electrode 230 may not perform non-contact capacitive coupling with the first outer RF electrode 210, and only the outer ring 234 of the second outer RF electrode 230 may perform non-contact capacitive coupling with the first outer RF electrode 210. Thus, the inner ring 232 of the second outer RF electrode 230 may not be substantially connected to the first outer RF electrode 210.

Accordingly, the substrate support 10 according to the present disclosure may include one or more straight jumpers 236 (also referred to herein as “jumpers”) that connect the inner ring 232 and the outer ring 234, so that the first outer RF electrode 210 and the inner ring 232 of the second outer RF electrode 230 may be electrically connected. In addition, because one end of the outer electrode conductor 250 is finally connected to the inner ring 232 of the second outer RF electrode 230, the outer electrode conductor 250 may be electrically connected to both the first outer RF electrode 210 and the second outer RF electrode 230. That is, there is an effect in which the outer electrode conductor 250 may be electrically connected to the first outer RF electrode 210 without directly connecting the outer electrode conductor 250 to the first outer RF electrode 210 disposed at an uppermost portion.

In the substrate support 10 according to the present disclosure, in order for the outer electrode conductor 250 connected to the inner ring 232 of the second outer RF electrode 230 to penetrate the shaft 130 without bending, the outer electrode conductor 250 may be connected to the second outer RF electrode 230 at least within a range where the hollow inner portion of the shaft 130 is connected.

FIG. 7 shows four straight jumpers 236 connecting the inner ring 232 and the outer ring 234, but the number of straight jumpers 236 is not limited.

However, the jumper 236 in the present disclosure that connects the inner ring 232 and the outer ring 234 (substantially, the first outer RF electrode 210 and the inner ring 232) and has a straight shape may prevent the cracking caused by heat from occurring due to the low sinterability in a conventional bent connection structure, so that a shape of jumper 236 in the present disclosure is limited to the straight shape.

FIG. 8 is a view shown to describe an RF electrode of the substrate support according to an embodiment.

FIG. 8 shows an embodiment of the second outer RF electrode 230 having a different shape from that of the embodiment of FIG. 7. The second outer RF electrode 230 may have a disk shape with the hole 233 through which the inner electrode conductor 240 passes.

In this case, when one end of the outer electrode conductor 250 is connected to any portion of the second outer RF electrode 230 disposed below the first outer RF electrode 210 and performing non-contact capacitive coupling with the first outer RF electrode 210, the outer electrode conductor 250 may be substantially electrically connected to both the first outer RF electrode 210 and the second outer RF electrode 230.

Similar to the embodiment of FIG. 7, in order for the outer electrode conductor 250 to penetrate the shaft 130 without bending, the outer electrode conductor 250 may be connected to the second outer RF electrode 230 at least within a range where the hollow inner portion of the shaft 130 is connected.

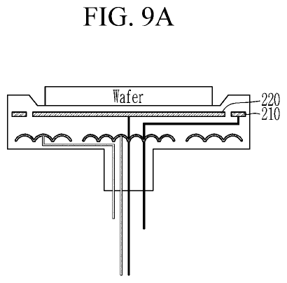

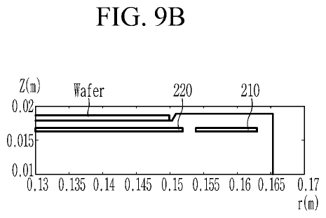

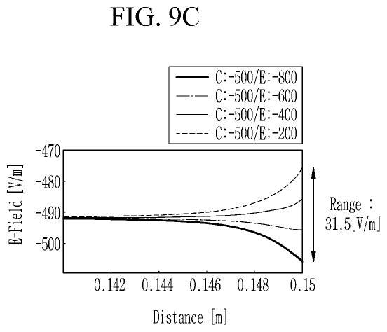

FIGS. 9A to 11C are views shown to describe an effect of the substrate support according to embodiments, and are views shown to describe a variable range of an electric field of the substrate support 10 according to the present disclosure.

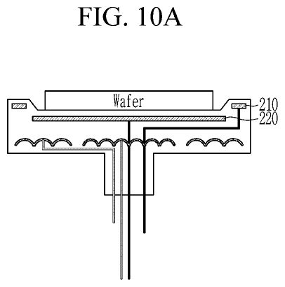

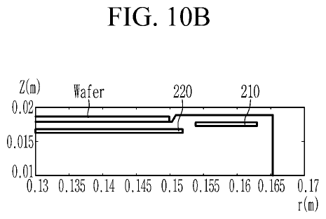

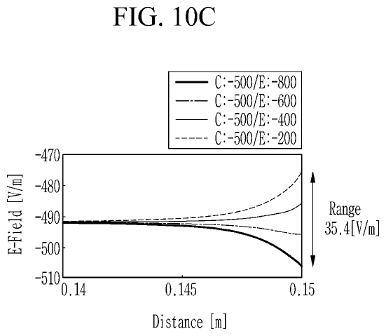

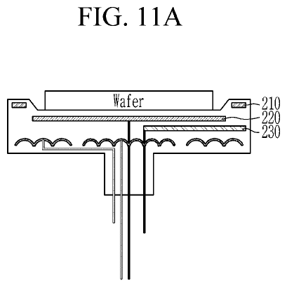

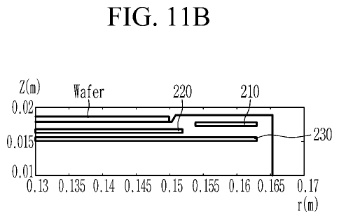

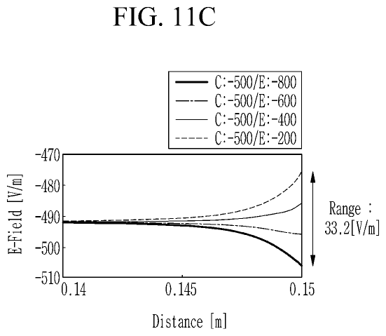

FIG. 11A shows the substrate support 10 according to the present disclosure, and FIG. 9A or 10A shows an example of a substrate support (that is, a substrate support different from a structure in which the RF electrode 200 including the outer RF electrodes 210 and 230 and the inner RF electrode 220 is disposed) for comparison with the substrate support 10 according to the present disclosure.

FIG. 9A, FIG. 10A, and FIG. 11A show substrate supports with different RF electrodes, and each of FIG. 9B, FIG. 10B, and FIG. 11B is a graph that makes it easy to grasp a disposition structure of the RF electrode 200 and a distance between the RF electrodes within the substrate support of each of FIG. 9A, FIG. 10A, and FIG. 11A.

FIG. 9C, FIG. 10C, and FIG. 11C are graphs comparing electric fields of FIG. 9A, FIG. 10A, and FIG. 11A and checking an electric field variable range.

First, referring to FIG. 9A and FIG. 9B, it may be seen that the inner RF electrode 220 is disposed parallel to the substrate disposition surface below the substrate disposition surface of the substrate support and the outer RF electrode 210 that has a ring shape and surrounds the inner RF electrode 220 is disposed on the same plane as the inner RF electrode 220. Unlike the outer RF electrode of the present disclosure, the outer RF electrode 210 of FIG. 9A is a single electrode.

FIG. 9C is a graph comparing electric fields according to a disposition structure of the inner RF electrode 220 and the outer RF electrode 210 within the substrate support of FIG. 9A, and the variable range of the electric field on a surface of the substrate disposed at the substrate support of FIG. 9A is confirmed to be 31.5 V/m.

Next, the substrate support of FIG. 10A and FIG. 10B may include the inner RF electrode 220 disposed in parallel with the substrate disposition surface below the substrate, and the outer RF electrode 210 that has a shape surrounding the inner RF electrode 220 may be disposed higher than the inner RF electrode 220 in the substrate support of FIG. 10A and FIG. 10B. That is, a height at which the outer RF electrode 210 is disposed with respect to a lower cross-section is higher than a height at which the inner RF electrode 220 is disposed with respect to the lower cross-section.

FIG. 10C is a graph comparing electric fields according to a disposition structure of the inner RF electrode 220 and the outer RF electrode 210 within the substrate support of FIG. 10A, and the variable range of the electric field on a surface of the substrate disposed at the substrate support of FIG. 10A is confirmed to be 35.4 V/m. Similar to the embodiment of FIG. 9A, the outer RF electrode 210 of FIG. 10A is a single electrode.

When FIG. 9C and FIG. 10C are compared, the variable range of FIG. 10C may be larger than that of FIG. 9C. This is because a distance between the substrate and the outer RF electrode 210 of FIG. 10A is closer than that of FIG. 9A.

Next, as shown in FIG. 1, FIG. 11A and FIG. 11B showing the substrate support 10 according to the present disclosure may include the first outer RF electrode 210 that surrounds the outside of the substrate disposition surface 110, the inner RF electrode 220 disposed in parallel with the substrate disposition surface 110 below the substrate disposition surface 110, and the second outer RF electrode 230 disposed below the inner RF electrode 220. The first outer RF electrode 210 of FIG. 11A may be disposed on a plane higher than a height at which the inner RF electrode 220 is disposed.

FIG. 11C is a graph comparing electric fields according to a RF electrode disposition structure of the substrate support 10 of FIG. 11A, and the variable range of the electric field on a surface of the substrate disposed at the substrate support of FIG. 11A is confirmed to be 33.2 V/m. It may be seen from this that the variable range of the electric field of the substrate support 10 shown in FIG. 11A is as much as the variable range of the electric field of the substrate support shown in each of FIG. 9A and FIG. 10A.

FIG. 9A or FIG. 10A shows a structure in which the outer electrode conductor is directly connected to a single outer RF electrode 210, but FIG. 11 shows a structure in which the outer electrode conductor is not directly connected to the first outer RF electrode 210 and the outer electrode conductor is connected to the second outer RF electrode 230 performing non-contact capacitive coupling with the first outer RF electrode 210. There is a difference between the structure of FIG. 9A or FIG. 10A and the structure of FIG. 11, but the variable range of the electric field of FIG. 11C has a similar result to that of FIG. 9C or FIG. 10C.

It is significant that the variable range of the electric field of FIG. 11A has a value similar to the variable range of the electric field of FIG. 9A or FIG. 10A even though the structure for connecting the electrode is changed as shown in FIG. 11A, and an effect according to the structure change will be described below.

In order to allow the outer electrode conductor connected to the outer RF electrode 210 disposed at an upper portion to pass through the shaft of the substrate support, the outer electrode conductor of the structure of FIG. 9A or FIG. 10A is twice bent or the structure of FIG. 9A or FIG. 10A inevitably includes a jumper with a bent structure. It may be seen in the drawings that the outer electrode conductor connected to a lower portion of the outer RF electrode 210 of the structure of FIG. 9A or FIG. 10A has a structure that is twice bent in order to pass through the shaft.

In contrast, the second outer RF electrode 230 performing non-contact capacitive coupling with the first outer RF electrode 210 may be disposed below the inner RF electrode 220 in the structure of FIG. 11A. Thus, the second outer RF electrode 230 may not be obscured by the inner RF electrode 220, and may extend to the region where the hollow inner portion of the shaft is projected.

Accordingly, there is a big difference between the structure of FIG. 11A and the structure of FIG. 9A or FIG. 10A in that the outer electrode conductor 250 connected to the second outer RF electrode 230 to pass through the shaft does not need to have a bent shape.

When the electrode conductor includes a portion that is twice bent as shown in FIG. 9A and FIG. 10A, there is a problem in which the cracking caused by heat occurs due to poor sinterability in the bent portion at the high temperature of 650 degrees or higher. However, in the substrate support 10 according to the present disclosure for improving this problem, the electrode conductor does not include the bent portion as shown in FIG. 11A so that the cracking caused by heat does not occur.

In other words, the substrate support 10 according to the present disclosure may be used without temperature restriction. Particularly, the structure of FIG. 11A may change a disposition of the outer RF electrodes 210 and 230 to remove the portion having the low sinterability so that it prevents the cracking caused by heat from occurring even at the high temperature of 650 degrees or higher. Further, it is significant that the variable range of the electric field of the substrate support 10 of FIG. 11A has a value similar to the variable range of the electric field of a conventional art of FIG. 9A or FIG. 10A.

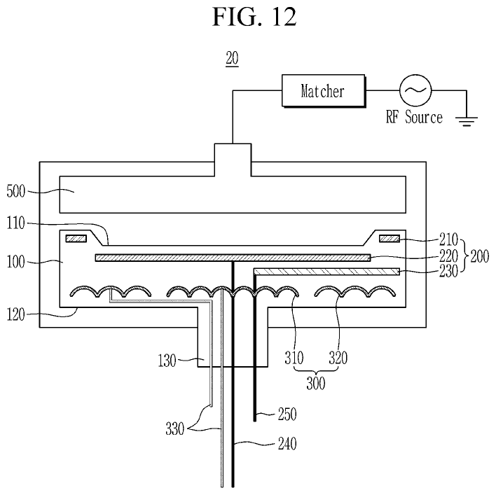

FIG. 12 is a view shown to describe a thin film processing device according to an embodiment.

As shown in FIG. 12, the thin film processing device 20 according to the present disclosure may include the substrate support 10 including the body portion 100 having the substrate disposition surface 110 at an upper portion thereof, the RF electrode 200 disposed inside the body portion 100, the heater electrode 300 disposed below the RF electrode 200, and the shaft 130 formed on the lower portion surface 120 disposed at an opposite side of the substrate disposition surface 110 and having the hollow inner portion, and a shower head 500 disposed in parallel with the substrate support 10 above the substrate support 10 and including an upper electrode of ground potential (or a ground electric potential).

As described in FIGS. 1 to 8, the substrate support 10 of the thin film processing device 20 according to the present disclosure may have a structure in which the first outer RF electrode 210, the inner RF electrode 220, and the second outer RF electrode 230 of the RF electrode 200 that are spaced apart from each other are stacked from the substrate disposition surface 110 and are stacked in an order of the first outer RF electrode 210, the inner RF electrode 220, and the second outer RF electrode 230. The first outer RF electrode 210 and the second outer RF electrode 230 may be coupled by a non-contact capacitive coupling method.

In addition, the substrate support 10 may include the inner electrode conductor 240 having one end connected to the inner RF electrode 220 to penetrate the shaft 130 and the outer electrode conductor 250 having one end connected to the second outer RF electrode 230 to penetrate the shaft 130. The inner electrode conductor 240 and the outer electrode conductor 250 are connected to the first impedance controller 410 and the second impedance controller 420 to independently control the impedance. In addition, temperatures of the plurality of heater electrodes 300 may be adjusted through the temperature controller 340.

As shown in FIGS. 1 to 5 and FIGS. 7, 8, 11, and 12, the inner electrode conductor 240 for the inner electrode and the outer electrode conductor 250 for the outer electrode in the substrate support 10 according to the present disclosure are each can have a straight line shape without bending.

Specifically, in the inner electrode conductor 240, one end of which is connected to the inner RF electrode 220 and penetrates the shaft 130, the inner electrode conductor 240 from the one end to the part passing through the shaft 130 may have a single straight shape. In addition, in the outer electrode conductor 250, one end of which is connected to the second outer RF electrode 230 and penetrates the shaft 130, the outer electrode conductor 250 from the one end to the part passing through the shaft 130 may have a single straight s shape.

The thin film deposition control method using the substrate support 10 and the thin film processing device 20 according to the present disclosure that is a thin film deposition process through plasma treatment may include an operation in which RF electric power is supplied to perform non-contact capacitive coupling between the first outer RF electrode 210 and the second outer RF electrode 230, an operation in which the impedance controller 400 controls impedance of the inner RF electrode 220 and impedance of the second outer RF electrode 230, and an operation in which the temperature controller 340 controls a temperature of the heater electrode 300.

The operation of controlling the impedance may include an operation in which the first impedance controller 410 controls the impedance of the inner RF electrode 220 and an operation in which the second impedance controller 420 controls the impedance of the second outer RF electrode 230.

The operation of controlling the temperature may include an operation in which the first temperature controller 342 controls a temperature of the first heater electrode 310 disposed at the inside of the substrate disposition surface 110 based on a center of the substrate disposition surface 110 and an operation in which the second temperature controller 344 controls a temperature of the second heater electrode 320 disposed outside the first heater electrode 310.

The electrode conductors connected to the RF electrode 200 of the substrate support 10 according to the present disclosure do not have a bent structure with poor sinterability so that plasma treatment is performed at a temperature of 650 degrees or higher in a thin film deposition control process and there is no problem of the cracking caused by heat occurring within the substrate support 10 despite the high temperature process.

When the plurality of heater electrodes 300 are disposed in the thin film deposition process, independent adjustment of a thickness of the thin film and a physical property (or a k-value) of the thin film is required according to a temperature change due to the heater so that for the independent adjustment, the substrate support 10 according to the present disclosure includes the multi-electrode.

Particularly, the distribution control and the independent control of the physical property and the thickness may be performed through each controller, and in order to eliminate cracking caused by heat related to the low sinterability of the bent portion of the conventional art, a disposition structure of the outer RF electrodes 210 and 230 may be changed and the outer electrode conductor 250 connected to the outer RF electrode 230 may be straightened, so that the process may be performed at the temperature of 650 degrees or higher without the heat crack. Thus, a production yield may also be increased.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A substrate support comprising:
a body portion comprising:
substrate disposition surface on an upper portion thereof; and
a lower portion surface on a surface of the body portion opposite from the substrate disposition surface;
a radio frequency (RF) electrode disposed inside the body portion;
a heater electrode disposed between the RF electrode and the lower portion surface; and
a shaft that is formed on the lower portion surface, wherein the shaft comprises a hollow inner portion,
wherein the RF electrode comprises:
a first outer RF electrode disposed along a perimeter of the substrate disposition surface;
an inner RF electrode disposed parallel to and beneath the substrate disposition surface;
a second outer RF electrode disposed between the inner RF electrode and the heater electrode;
an inner electrode conductor having one end connected to the inner RF electrode, wherein the inner electrode conductor is disposed within the shaft; and
an outer electrode conductor having one end connected to the second outer RF electrode, wherein the outer electrode conductor is disposed within the shaft, and
wherein the first outer RF electrode, the inner RF electrode, and the second outer RF electrode are spaced apart from each other to have a non-contact structure.

2. The substrate support of claim 1, wherein the second outer RF electrode is configured to couple with the first outer RF electrode through non-contact capacitive coupling.

3. The substrate support of claim 1, wherein a radius of the second outer RF electrode is the same as a radius of the first outer RF electrode.

4. The substrate support of claim 1, wherein the first outer RF electrode is disposed on a plane higher than a height at which the inner RF electrode is disposed relative to the lower portion surface, or the first outer RF electrode is disposed on a same plane as the inner RF electrode.

5. The substrate support of claim 1, wherein the first outer RF electrode comprises a ring shape.

6. The substrate support of claim 1, wherein the first outer RF electrode is disposed parallel to the substrate disposition surface.

7. The substrate support of claim 5, wherein the first outer RF electrode comprises a shape that is inclined as the first outer RF electrode moves from an inner circumference of the ring shape to an outer circumference of the ring shape, and wherein the ring shape is disposed to have a constant angle with respect to the substrate disposition surface.

8. The substrate support of claim 1,
wherein the body portion further comprises:
a first body portion wherein the first outer RF electrode is disposed; and
a second body portion wherein the substrate disposition surface, the inner RF electrode, the second outer RF electrode, and the heater electrode are disposed, and
wherein the first body portion and the second body portion are spaced apart from each other.

9. The substrate support of claim 1, wherein the inner RF electrode comprises a disk shape.

10. The substrate support of claim 1, wherein the second outer RF electrode comprises a disc shape including a hole.

11. The substrate support of claim 1, wherein the second outer RF electrode comprises:
an inner ring comprising a hole through which the inner electrode conductor passes and which is connected to the one end of the outer electrode conductor;
an outer ring that is spaced apart from the inner ring and is formed on a same plane as the inner ring; and
one or more jumpers connecting the inner ring and the outer ring.

12. The substrate support of claim 1, wherein the inner electrode conductor is connected to a first impedance controller and the outer electrode conductor is connected to a second impedance controller.

13. The substrate support of claim 1,
wherein the heater electrode comprises a plurality of heater electrodes disposed on a plane, and
wherein each of the plurality of heater electrodes is connected to a heater electrode conductor from among a plurality of heater electrode conductors.

14. The substrate support of claim 1, wherein the heater electrode comprises:
a first heater electrode disposed inside of the perimeter of the substrate disposition surface; and
a second heater electrode disposed on a side of the first heater electrode closest to the perimeter of the substrate disposition surface.

15. The substrate support of claim 13, wherein each heater electrode conductor of the plurality of heater electrode conductors is connected to a temperature controller from among a plurality of temperature controllers.

16. A substrate support comprising:
a body portion comprising:
a substrate disposition surface on an upper portion thereof; and
a lower portion surface on a surface of the body portion opposite from the substrate disposition surface;
a radio frequency (RF) electrode disposed inside the body portion;
a heater electrode disposed between the RF electrode and the lower portion surface; and
a shaft that is formed on the lower portion surface, wherein the shaft comprises a hollow inner portion,
wherein the RF electrode comprises:
a first outer RF electrode,
an inner RF electrode,
a second outer RF electrode,
an inner electrode conductor having one end connected to the inner RF electrode, wherein the inner electrode conductor is disposed within the shaft, and
an outer electrode conductor having one end connected to the second outer RF electrode, wherein the outer electrode conductor is disposed within the shaft,
wherein the inner electrode conductor and the outer electrode conductor each have a straight line shape,
wherein the first outer RF electrode, the inner RF electrode, and the second outer RF electrode are spaced apart from each other in a stacked configuration,
wherein within the stacked configuration the first outer RF electrode is closest to the substrate disposition surface, the inner RF electrode is next closest to the substrate disposition surface, and the second outer RF electrode is farthest from the substrate disposition surface,
wherein the first outer RF electrode and the second outer RF electrode are configured to couple through non-contact capacitive coupling, and
wherein the inner electrode conductor is connected to a first impedance controller and the outer electrode conductor is connected to a second impedance controller, and each of the first impedance controller and the second impedance controller are configured to independently control an impedance of the inner electrode conductor and the outer electrode conductor, respectively.

17. The substrate support of claim 16, wherein a radius of the second outer RF electrode is the same as a radius of the first outer RF electrode.

18. The substrate support of claim 16, wherein the first outer RF electrode is disposed on a plane higher than a height at which the inner RF electrode is disposed relative to the lower portion surface, or the first outer RF electrode is disposed on a same plane as the inner RF electrode.

19. The substrate support of claim 16, wherein the first outer RF electrode comprises a ring shape and is disposed parallel to the substrate disposition surface.

20. The substrate support of claim 16, wherein the second outer RF electrode comprises:
an inner ring comprising a hole through which the inner electrode conductor passes and which is connected to the one end of the outer electrode conductor,
an outer ring that is spaced apart from the inner ring and is formed on a same plane as the inner ring; and
one or more jumpers connecting the inner ring and the outer ring.
